(19) United States
(12) Patent Application Publication
(10) Pub. No.: US 2022/0415671 A1
(43) Pub. Date: Dec. 29, 2022

(54) COOLING OF HIGH POWER DEVICES USING SELECTIVE PATTERNED DIAMOND SURFACE

(71) Applicant: Soreq Nuclear Research Center, Yavne (IL)

(72) Inventors: Bruno Sfez, Yavne (IL); Oren Steinberg, Yavne (IL); Irina Gouzman, Yavne (IL); Asaf Bolker, Yavne (IL)

(73) Assignee: Soreq Nuclear Research Center, Yavne (IL)

(21) Appl. No.: 17/787,596

(22) PCT Filed: Dec. 24, 2020
(86) PCT No.: PCT/IB2020/062432

§ 371 Date: Jun. 21, 2022

Related U.S. Application Data
(60) Provisional application No. 62/953,558, filed on Dec. 25, 2019.

(51) Int. Cl. H01L 21/48; H01L 23/373

(52) U.S. Cl. CPC H01L 21/4871; H01L 23/3732

(57) ABSTRACT

A method for efficient heat removal from a semiconducting device made from III-V semiconductor crystals includes depositing a diamond seeding layer on a patterned substrate.

### FIELD OF THE INVENTION

The present invention relates to a method for efficiently extract heat from a semiconductor surface emitting device by employing a selective area growth of the semiconductor in diamond patterned structure.

### BACKGROUND OF THE INVENTION

Semiconductor surface emitting devices constitute a very important class of light emitting devices that comprise vertical cavity surface emitting lasers (VCSEL's), optically pumped disk lasers, micro-LED's and a plethora of mixed devices. Major advantages of such devices include high light extraction efficiency, built-in scalability, light mode quality inter alia. However, for high power applications, these devices lack proper heat extraction mechanism. This is due to their basic configuration: the physical contact between the device and the substrate is substantially smaller than for edge emitting devices. Moreover, the active region, where the heat is generated, is usually relatively far from the substrate, being separated from this substrate by a large number of layers, such as Bragg mirrors for example. Finally, since III-V crystals display relatively poor heat conductivity, heat is accumulated within the device and deteriorates its output (GaAs thermal conductivity coefficient is 0.55 W cm¹° C.⁻¹ compared to 1.3 W cm¹° C.⁻¹ for silicon).

This situation strongly hampers the development of high power devices and reduces the quality of the emitted light (mode distortion).

Currently, the state of the art for heat removal is either to mount them directly, or with a highly heat conductive heat-spreader, on a copper heat-sink.

Recently, to further improve heat extraction, new VECSEL designs have been proposed by employing two diamond heat-spreaders top and bottom (diamond-sandwich approach), either by diamond deposition or bonding. However, for both approaches, heat must diffuse through the whole structure in order to reach the bottom or the top of the device, from where it can be extracted.

For high power emission these approaches are not sufficient and more efficient heat extraction has to be provided.

### SUMMARY OF THE INVENTION

The present invention seeks to provide a method to embed semiconductor light emitting devices in a diamond surrounding so that each region of the device is in close contact with diamond. Since diamond is the best heat-spreader, this method leads to optimal heat extraction.

### BRIEF DESCRIPTION OF THE DRAWINGS

FIG. 1 is a simplified illustration of a process for diamond deposition on a semiconductor, in accordance with an embodiment of the invention. 101 is the semiconductor substrate, 102 after dielectric coating, 103 after dielectric material patterning, 104 after seeding, 105 after photoresist removal, 106 after CVD diamond growth, 107 after dielectric removal, and 108 after semiconductor layers' epitaxial growth.

FIG. 2 is a simplified illustration of creating thermally-conductive vias or paths for thermally connecting the diamond covered areas of the device to a heat exchanger, in accordance with an embodiment of the invention.

### DETAILED DESCRIPTION OF THE INVENTION

The present invention provides an approach for producing a semiconductor surface emitting device with highly efficient heat extraction in order to enable high output, high quality power emitting device.

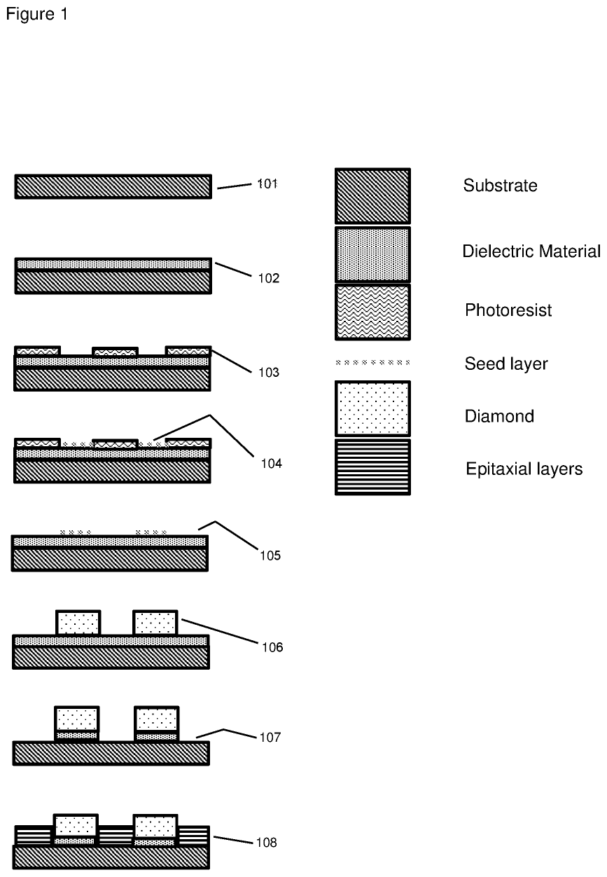

In order to do so, a diamond layer is grown on a semiconductor substrate. Reference is made to FIG. 1, which describes a process for doing so, in accordance with an embodiment of the invention.

Starting from a semiconductor substrate 101, a dielectric material (such as silicon oxide, silicon nitride or any other material suitable for seeding with diamond particles) layer is deposited (102) and then a photoresist (PR) (or any other material that can be patterned by lithography) layer is deposited and patterned by lithography (103), determining areas with PR and areas without PR on the dielectric material surface. Next, a diamond seeding layer, such as diamond slurry, is deposited on the wafer (104). The photoresist is then removed, leaving a patterned diamond seeded surface on the wafer (105).

A diamond layer is deposited, for example by chemical vapor deposition technique (CVD). It should be noted that the diamond will grow preferentially on the regions that have been seeded. Residual growth might occur on the non-seeded regions, however with a very sparse density (islands-like growth), which is easy to remove in the following processes.

Deposition of diamond is done at high temperature range (>650° C.), which is not applicable on a semiconductor device without protection, as the semiconductor (such as GaAs, InP, GaSb) surface thermally decomposes. Therefore, the dielectric layer has a dual purpose: prevent diamond growth on non-seeded regions on the wafer, and act as nucleation areas for diamond particles in the seeded areas (106).

Then, using an etching process, the dielectric layer in the non-seeded areas is removed, leaving an intact semiconductor surface. This process finally results in open semiconductor substrate selected areas surrounded by a diamond layer (107). It should be noted that thick diamond layers can be deposited in this way.

Following this, semiconductor layers are grown, for example using MOCVD (metal organic chemical vapor deposition) or MBE (molecular beam epitaxy) techniques (108). The growth is selective, being effective only in the selected areas where the semiconductor surface is open, free from diamond. The epitaxial layers are grown on the semiconductor surface (e.g. GaAs, InP, GaSb, GaN and alloys of these) and not on the diamond surface. According to the growth conditions, the epitaxial structure might be in contact with the diamond or very close. For thermal conduction, this is less critical than for electric conduction. and the diamond layer which will act as a heat spread layer.

Another issue arises from the fact that the grown diamond layer surface may be hydrogen terminated, as a result of the hydrogen rich growth environment. The hydrogenation of the diamond surface may result in negative electron affinity, pulling the vacuum level below the conduction band minimum (up to −1.3 eV). This can result in charge transfer between the valence band of the diamond and conduction band of the device layer, thus turning the diamond into a P-type semiconductor and injecting unwanted electrons into the device layers. Possible methods to prevent this charge transfer include:

1. Surface oxidation, which will result in a diamond surface with a positive electron affinity of 1.7 eV, as shown by Ristein (J., Surface science of diamond: Familiar and amazing. Surface Science, 2006. 600(18): p. 3677-3689).

2. Deposition of a thin insulating layer with large band gap and sufficiently small electron affinity, such as SiO₂.

This technique enables a near-contact to full contact of the semiconductor side walls and the diamond layer which will act as a heat spread layer.

This technique enables a highly efficient heat extraction needed for high power devices, as heat generated in the active region of the device is very close to the diamond heat sink layer, resulting in a higher heat extraction efficiency compared to other techniques where the heat sink is located at a much higher distance from the active region.

The diamond layer is then connected to a heat exchanger or a thermoelectric cooler.

In order to remove heat efficiently, it is preferable to connect the diamond covered areas to a heat exchanger located at close proximity. A convenient way to do so is through vias filled with a thermally conducting material such as copper, indium or diamond.

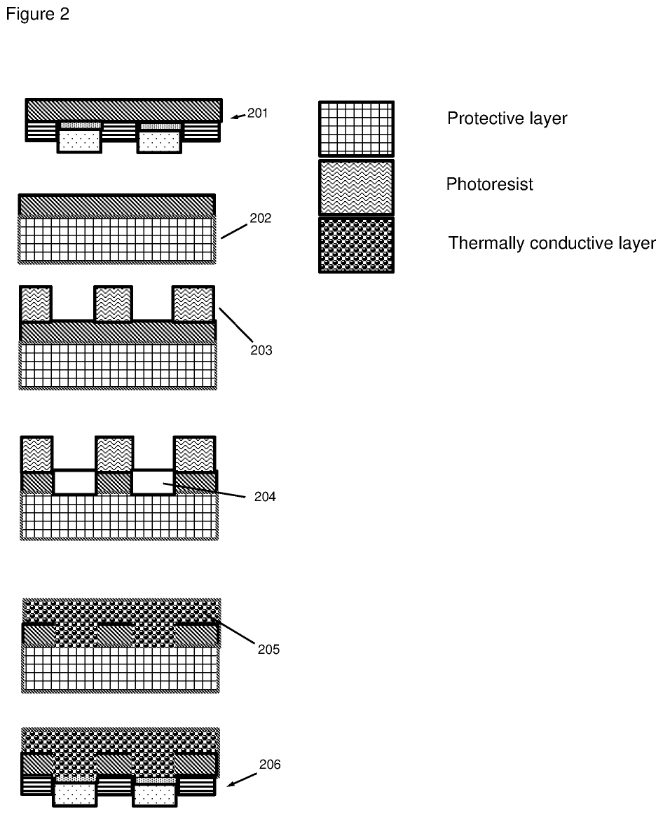

The process is illustrated in FIG. 2:

After optionally thinning the wafer, starting from the grown device 201, a protective layer such as photoresist is deposited on the grown side of the wafer in order to protect the structures (202). Then a photoresist layer is deposited on the other side of the wafer and is patterned so as to leave holes that are correspondingly in front of the regions where the diamond has been grown previously (203). The wafer is then etched until the diamond layer is reached (204). The holes (204) are then filled with the thermally conducting material (205). The protective layer can then be removed (206). The wafer can then be cut into individual devices, and each device can be put in thermal contact with a passive or active heat sink.

It should be noted that the thermally conducting material can be a metal, such as copper. In such a case, this layer can be pattern by itself in order to provide electric contact to the devices.

1. A method for efficient heat removal from a semiconductor device comprising:
depositing a dielectic material (102) on a wafer surface of a semiconductor substrate (101);
depositing and patterning a photoresist layer (103) on top of said dielectric material (102);
depositing a diamond seeding layer (104) on said semiconductor substrate (101);
removing said photoresist layer (103) and leaving a patterned diamond seeded surface (105) on said semiconductor substrate (101);
depositing a diamond layer (106) on said patterned diamond seeded surface (105);
removing said dielectric material (102) from areas not seeded with said diamond seeding layer (104), leaving an area (107) on said semiconductor substrate (101) with no said diamond layer (106); and
depositing a semiconducting structure (108) on said area (107).

2. The method according to claim 1, wherein said semiconducting structure (108) is a III-V semiconducting structure.

3. The method according to claim 1, wherein said dielectric material (102) comprises silicon oxide or silicon nitride.

4. The method according to claim 1, wherein said seeded surface (105) comprises a diamond slurry.

5. The method according to claim 1, wherein said diamond layer (106) is deposited using a chemical vapor deposition technique at a temperature above 650° C.

6. The method according to claim 1, wherein vias are produced in the wafer surface and filled with a thermally conducting material (205).

7. The method according to claim 6, wherein the vias are produced using the following steps:
covering a side of the wafer surface that has said diamond layer (106) with a protective layer (202);
depositing a photoresist layer (203) on an opposite side of the wafer surface;
patterning said photoresist layer (203) so as to leave holes (204) that are aligned with regions where diamond has been grown previously;
etching vias in the wafer surface until the diamond layer (106) is reached;
removing the photoresist layer (203);
filling said vias with a thermally conducting material (205) and covering the entire wafer surface said thermally conducting material (205); and
removing the protective layer (202).

8. The method according to claim 7, wherein the thermally conducting material (205) comprises copper.

9. The method according to claim 7, wherein the thermally conducting material (205) is patterned in order to provide electrical contacts.
